(19) United States
(12) Patent Application Publication
(10) Pub. No.: US 2015/0208518 A1
(43) Pub. Date: Jul. 23, 2015

(54) REMOVABLE COPPER FOIL ATTACHED SUBSTRATE AND METHOD FOR PRODUCING CIRCUIT BOARD

(71) Applicant: Panasonic Intellectual Property Management Co., Ltd., Osaka-shi, Osaka (JP)

(72) Inventors: Kentaro Fujino, Fukushima (JP); Tatsuo Yonemoto, Fukushima (JP); Hirofumi Midorikawa, Fukushima (JP); Yasunori Anbe, Fukushima (JP)

(73) Assignee: Panasonic Intellectual Property Management Co. Ltd, Osaka-shi, Osaka (JP)

(21) Appl. No.: 14/420,797

(22) PCT Filed: Aug. 29, 2013
(86) PCT No.: PCT/JP2013/005095

§ 371 Date: Feb. 10, 2015

(30) Foreign Application Priority Data
Aug. 31, 2012 (JP) 2012-192153

(51) Int. Cl. H05K 3/46

(52) U.S. Cl. CPC H05K 3/4682

(57) ABSTRACT

It is an object of the present invention to provide a removable copper foil attached substrate capable of easily producing a coreless circuit board at low production cost and low raw material cost as compared with a conventional example. The substrate includes a release resin layer attached copper foil including a copper foil and a release resin layer attached on a surface of the copper foil; and a support layer. The release resin layer attached copper foil is integrally bonded to the support layer with the release resin layer in-between. The release resin layer allows removal of the copper foil from the support layer. A peel strength for removal of the copper foil from the support layer is 20 to 300 N/m.

### TECHNICAL FIELD

The present invention relates to a removable copper foil attached substrate and a method for producing a circuit board using the same.

### BACKGROUND ART

In the past, there has been proposed a method for producing a wiring board described in, for example, Patent Literature 1, as a method for producing a wiring board having no core material. In this method, an underlying layer is first disposed on a wiring formation region on prepreg. A copper foil having a size larger than that of the underlying layer is disposed on the prepreg with the underlying layer in-between so that the copper foil is brought into contact with an outer peripheral portion of the wiring formation region. The prepreg is cured with heating and pressing to obtain a temporary substrate from the prepreg. Concurrently, the copper foil is made to adhere to at least one surface of the temporary substrate. Next, a buildup wiring layer containing a wiring layer made of gold or the like is formed on the copper foil so that the buildup wiring layer is brought into contact with the copper foil. Then, the copper foil is separated from the temporary substrate by cutting a portion of a structure in which the underlying layer, the copper foil, and the buildup wiring layer are formed on the temporary substrate. The portion corresponds to a peripheral portion of the underlying layer. Thereby, a wiring member in which the buildup wiring layer is formed on the copper foil is obtained. A lower surface of a lowermost wiring layer of the buildup wiring layer is exposed by selectively eliminating the copper foil from the wiring layer made of gold or the like in the wiring member, to produce a coreless wiring board.

### PRIOR ART DOCUMENTS

### Patent Literature

Patent Literature 1: JP 4334005 B

### SUMMARY OF THE INVENTION

### Problems to be Resolved by the Invention

However, the method for producing the wiring board described in Patent Literature 1 makes it necessary to cut the peripheral portion in the step of separating the temporary substrate, which increases production man-hours for cutting, to increase production cost. The wiring board obtained by cutting the peripheral portion has a small size, which makes it necessary to previously design the temporary substrate and the buildup wiring layer to be large in consideration of cutting and eliminating the peripheral portion. Since it is difficult to reuse the portion cut and eliminated, the portion is disposed of, which increases raw material cost for disposing of. Furthermore, a residual portion of the separated temporary substrate has a size smaller than the initial size by cutting, which makes it difficult to reuse the residual portion for the other applications. The residual portion is obliged to be discarded.

The present invention was made in view of the above points. It is an object of the present invention to provide a removable copper foil attached substrate capable of easily producing a coreless circuit board at low production cost and low raw material cost as compared with a conventional example, and a method for producing a circuit board.

### Means of Solving the Problems

A removable copper foil attached substrate according to the present invention includes: a release resin layer attached copper foil including a copper foil and a release resin layer attached on a surface of the copper foil; and a support layer. The release resin layer attached copper foil is integrally bonded to the support layer with the release resin layer in-between. The release resin layer allows removal of the copper foil from the support layer. A peel strength for removal of the copper foil from the support layer is 20 to 300 N/m.

In the removable copper foil attached substrate, the one surface of the copper foil on which the release resin layer is provided is preferably a shiny surface.

In the removable copper foil attached substrate, a further surface of the copper foil is preferably a matte surface.

In the removable copper foil attached substrate, preferably, the release resin layer attached copper foil is integrally attached to each of both surfaces of the support layer.

In the removable copper foil attached substrate, the support layer is preferably made from prepreg prepared by impregnating base material with resin.

A method for producing a circuit board according to the present invention is a method for producing at least one circuit board by use of the removable copper foil attached substrate as a temporary substrate, The method includes: a buildup step of preparing a laminated structure by forming at least one circuit board layer on the removable copper foil attached substrate by performing a step of forming an insulating layer on a copper foil of the removable copper foil attached substrate and a patterned wire on the insulating layer by patterning techniques involving chemical treatment and an optional step of performing at least one time sub-step of an additional insulating layer and an additional patterned wire; and a removing step of removing the copper foil from the support layer in the laminated structure to separate the at least one circuit board layer serving as the at least one circuit board.

### Effect of the Invention

Since the copper foil is removable from the support layer in the removable copper foil attached substrate according to the present invention, the circuit board can be obtained by separating the temporary substrate without requiring a cutting step in a production process when the circuit board is produced on the surface of the copper foil by a buildup method or the like by use of the removable copper foil attached substrate as the temporary substrate. Thereby, the coreless circuit board can be easily produced at low production cost and low raw material cost as compared with a conventional example. The peel strength for removal of the copper foil from the support layer is 20 N/m or more. Thereby, when the patterned wire is formed in the production process of the circuit board, a chemical used for the chemical treatment is less likely to sink into an interface between the copper foil and the support layer, and the erosion of the copper foil can be suppressed. The peel strength for removal of the copper foil from the support layer is 300 N/m or less. Thereby, when the circuit board is produced, the generation of strain in the circuit board obtained by removing the copper foil from the support layer can also be suppressed.

### BRIEF DESCRIPTION OF DRAWINGS

FIG. 1 is a sectional view showing an example of a removable copper foil attached substrate;

FIG. 2 is a sectional view showing an example of a method for producing a removable copper foil attached substrate;

FIGS. 3A to 3D are sectional views showing an example of a method for producing a circuit board;

FIG. 4 is a perspective view showing an example of an apparatus for measuring a peel strength;

FIG. 5 is a perspective view showing an example of a laminated structure subjected to router processing; and

FIG. 6 is a photograph showing bits used for router processing.

### DESCRIPTION OF EMBODIMENTS

Hereinafter, an embodiment of the present invention will be described.

First, a removable copper foil attached substrate 5 will be described.

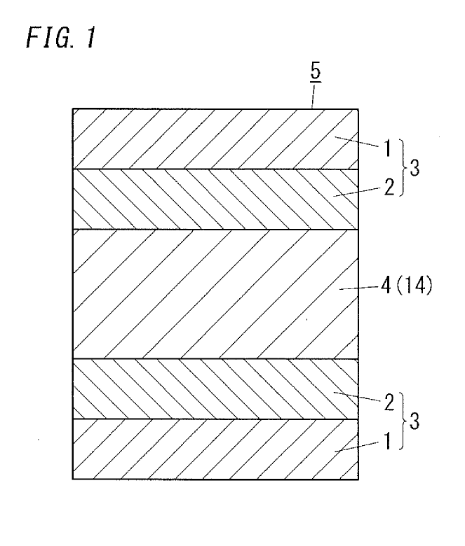

As shown in FIG. 1, the removable copper foil attached substrate 5 is formed by integrally bonding a release resin layer attached copper foil 3 to a support layer 4. The release resin layer attached copper foil 3 is formed by providing a release resin layer 2 on one surface of a copper foil 1. The release resin layer attached copper foil 3 is integrally bonded to the support layer 4 with the release resin layer 2 in-between. The copper foil 1 is bonded to the support layer 4 with the release resin layer 2 in-between. The copper foil 1 is removable from the support layer 4 by applying a mechanical external force if needed.

In the removable copper foil attached substrate 5 described herein, as shown in FIG. 1, the release resin layer attached copper foil 3 is integrally bonded to each of both surfaces of the support layer 4. In this case, a circuit board layer 12 can be formed on each of both surfaces of the removable copper foil attached substrate 5 by a buildup method when a circuit board 9 is produced by use of the removable copper foil attached substrate 5 as a temporary substrate as described later, which improves the production efficiency of the circuit board 9. The release resin layer attached copper foil 3 may be integrally bonded to only one surface of the support layer 4 in accordance with the purpose.

For example, a copper foil generally used in the application of a copper clad laminated board can be used as the copper foil 1 used for the release resin layer attached copper foil 3 without particular limitation. The thickness of the copper foil 1 is also not particularly limited. For example, a copper foil with a thickness of 12 to 70 μm can be used. Practically, a copper foil with a thickness of 12 to 18 μm is preferably used.

The release resin layer 2 is formed so that one surface of the copper foil 1 is covered with the release resin layer 2. Examples of a method for forming the release resin layer 2 include a method for coating one surface of the copper foil 1 with a liquid release resin, and a method for transferring a film made of a release resin on the surface of the copper foil 1 or making the film adhere to the surface by use of an adhesive or a pressure-sensitive adhesive. The release resin used herein is not particularly limited as long as the release resin can exhibit a predetermined peel strength (described later) when the release resin layer attached copper foil 3 is removed from the support layer 4. Examples of the release resin include a release resin such as a fluorine-based resin or a silicone-based resin, and a composite resin material obtained by adding a removal ingredient such as a fluorine-based ingredient or a silicone-based ingredient to a film-forming resin such as an epoxy resin. The thickness of the release resin layer 2 is also not particularly limited, and can be designed to provide a predetermined peel strength (described later) according to the thickness of the copper foil 1 and the type of the release resin. For example, practically, the thickness of the release resin layer 2 is preferably within a range of 0.5 to 2.0 μm. Since the peel strength tends to decrease with an increase in the thickness of the release resin layer 2, the releasability of the release resin layer 2 can also be adjusted by selecting a material used for the release resin in the relationship with the thickness of the release resin layer 2.

One surface (inner face) of the copper foil 1 on which the release resin layer 2 is provided is preferably a shiny surface. In this case, after the release resin layer attached copper foil 3 is removed from the support layer 4, the surface of the copper foil 1 can have a good state. Since the peel property of the release resin layer 2 from the copper foil 1 is improved, a material for a release resin used to form the release resin layer 2 is easily selected.

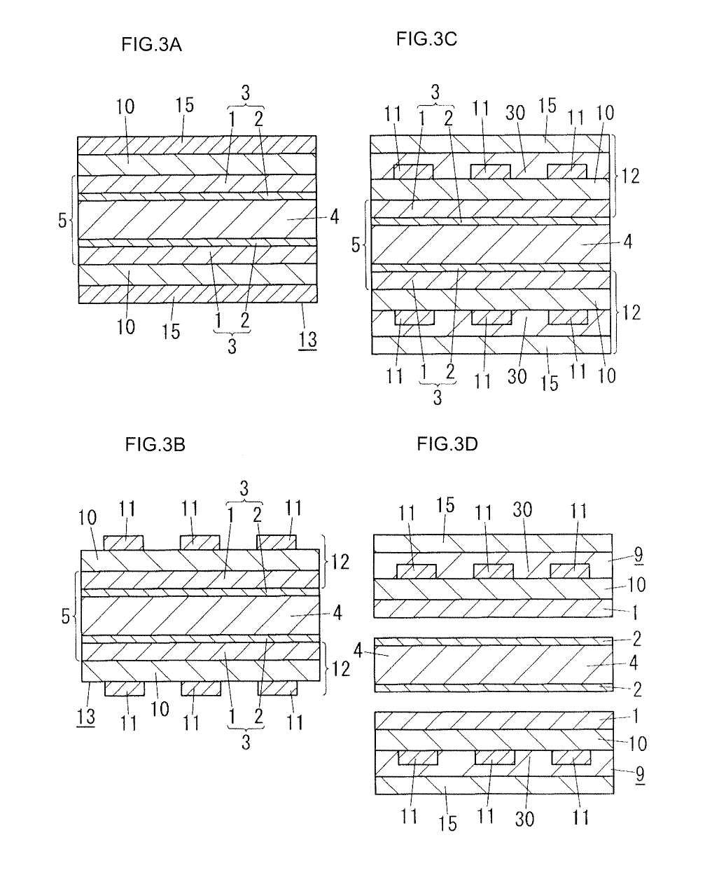

A further surface (outer surface) of the copper foil 1 which is a surface opposite to the surface on which the release resin layer 2 is provided is preferably a matte surface. When the circuit board layer 12 is formed on the copper foil 1 by a buildup method by use of the removable copper foil attached substrate 5 as a temporary substrate as described later in this case (see FIG. 3), the copper foil 1 can be firmly bonded to an insulating layer 10.

The release resin layer attached copper foil 3 is integrally bonded to the support layer 4 with the release resin layer 2 in-between, and thereby the removable copper foil attached substrate 5 is constituted. In this regard, the support layer 4 and the release resin layer attached copper foil 3 have substantially the same size in the plan view. A border between the support layer 4 and the release resin layer attached copper foil 3 appears on a side edge face of the removable copper foil attached substrate 5.

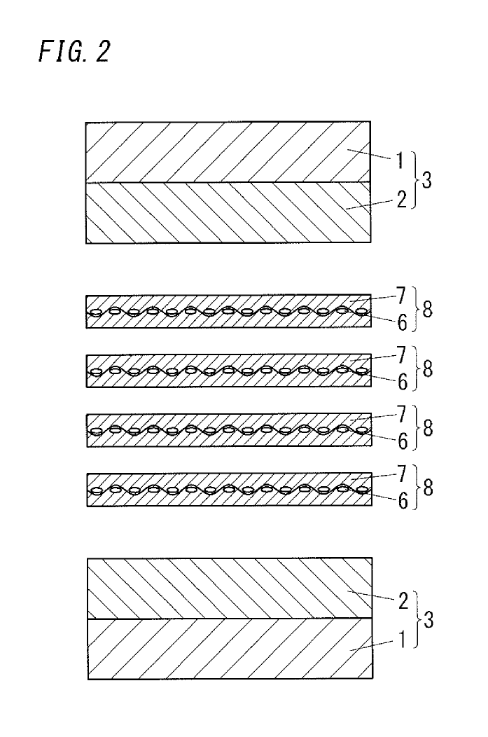

The support layer 4 has a plate-like shape, and can be integrally bonded to the release resin layer attached copper foil 3. The support layer 4 is not particularly limited as long as the copper foil 1 is removable from the support layer 4. The support layer 4 is preferably made from prepreg 8 prepared by impregnating base material 6 with resin 7. In this case, first, as shown in FIG. 2, the prepreg 8 and the release resin layer attached copper foil 3 are stacked so that the release resin layer 2 faces the prepreg 8. This is heated and pressure molded with a press-molding machine (omitted from the drawing), and thereby the resin 7 of the prepreg 8 is cured. As shown in FIG. 1, an insulating layer 14 serving as the support layer 4 is formed, and the release resin layer attached copper foil 3 is closely bonded to the insulating layer 14. The number of the prepregs 8 used in this case may be one, or more in order to obtain a desired thickness and rigidity, without particular limitation.

The above prepreg 8 can be produced by impregnating the base material 6 with a resin varnish, and heating and drying the base material 6 into a B stage state (semicured state). The resin varnish can be prepared by dissolving a resin composition in a solvent or the like. Although a resin ingredient in the resin composition is not particularly limited, the resin composition can be produced by blending a curing agent, a curing accelerator and/or the like with a thermosetting resin such as an epoxy resin, for example. An inorganic filler or the like may be blended if needed. In this case, the coefficient of thermal expansion of the support layer 4 can be reduced, and the warpage of the removable copper foil attached substrate 5 can be suppressed. Furthermore, when a circuit board 9 is produced by use of the removable copper foil attached substrate 5 as a temporary substrate as described later, the occurrence of warpage in the circuit board 9 can also be suppressed. The content of the inorganic filler is preferably 50 to 400 parts by mass based on 100 parts by mass of the resin ingredient. A fiber base material such as a glass woven fabric or a glass nonwoven fabric can be used as the base material.

In the removable copper foil attached substrate 5, the release resin layer 2 allows removal of the copper foil 1 from the support layer 4. In this case, a substantial removal interface may be an interface between the release resin layer 2 and the support layer 4, or an interface between the release resin layer 2 and the copper foil 1 but may not be limited particularly. When the removal interface is the former, the release resin layer 2 remains on the copper foil 1 after the copper foil 1 is removed. When it is necessary to expose the surface of the copper foil 1 bonded to the release resin layer 2, the release resin layer 2 may be removed by being subjected to chemical treatment or the like. In this case, when the surface on which the release resin layer 2 is provided is the shiny surface of the copper foil 1, the release resin layer 2 is cleanly and easily eliminated, which can suppress a residue from remaining on the surface of the copper foil 1. On the other hand, when the removal interface is the latter, the release resin layer 2 remains on the support layer 4 after the copper foil 1 is removed, which is suitable for exposing the surface of the copper foil 1 after being removed. Also in this case, when the surface on which the release resin layer 2 is provided is the shiny surface of the copper foil 1, the release resin layer 2 is cleanly and easily removed from the copper foil 1, and nonuniformity of a peel strength within the surface can also be decreased.

In the removable copper foil attached substrate 5, a peel strength for removal of the copper foil 1 from the support layer 4 is within a range of 20 to 300 N/m, preferably 50 to 300 N/m, and more preferably 120 to 300 N/m. When the peel strength is less than 20 N/m, and a patterned wire 11 is formed by performing chemical treatment such as etching or metal plating in the case where the circuit board layer 12 is formed as described later, a chemical may spread onto the interface for enabling the later removal, which causes the erosion of the copper foil 1. On the other hand, when the peel strength is more than 300 N/m, and the copper foil 1 is removed from the support layer 4 after the circuit board layer 12 is formed, stress having an effect on the circuit board layer 12 may be increased, which causes faults such as warpage and strain in the circuit board 9.

Next, a method for producing a circuit board 9 will be described.

The circuit board 9 can be produced by use of the above removable copper foil attached substrate 5. The removable copper foil attached substrate 5 is used as a temporary substrate serving as a support for a circuit board layer 12 in a buildup method as described later. The following explanation relates to the removable copper foil attached substrate 5 which includes release resin layer attached copper foils 3 on both sides of a support layer 4 as shown in FIG. 1. However, the removable copper foil attached substrate of the present invention is not limited to the aforementioned one. The layer construction of the circuit board 9 shown in FIG. 3 is also an example, and the layer construction of the present invention is not limited to this example.

The method for producing the circuit board 9 includes a buildup step shown in FIGS. 3A to 3C and a removing step shown in FIG. 3D.

First, in the buildup step, an insulating layer 10 is formed on a copper foil 1 of the removable copper foil attached substrate 5. As specifically shown in FIG. 3A, the insulating layer 10 and a metal foil 15 such as a copper foil are stacked in this order on each of the copper foils 1 of the removable copper foil attached substrate 5, and bonded by heating and pressing with a press-molding machine (not shown). An insulating layer containing a base material 6 such as the above-mentioned prepreg 8, and an adhesive sheet (adhesive film) which do not contain the base material 6, or the like can be used as the insulating layer 10. In place of using the metal foil 15, a metal conductive layer may be formed on the surface of the insulating layer 10 by plating treatment after the insulating layer 10 is formed.

Next, a patterned wire 11 made of a conductive material is formed on the insulating layer 10 by patterning techniques involving chemical treatment. As specifically shown in FIG. 3B, the metal foil 15 is patterned into a predetermined circuit shape by etching, and thereby the patterned wire 11 is formed on the surface of the insulating layer 10. As described above, the chemical treatment including the etching treatment, and may include metal plating treatment or the like. According to the aforementioned manner, the circuit board layer 12 including the copper foil 1, the insulating layer 10, and the patterned wire 11 can be formed on the removable copper foil attached substrate 5. It is possible to produce a laminated structure 13 in which the circuit board layers 12 individually formed on both sides of the support layer 4.

Furthermore, the circuit board layer 12 may be multilayered by repeatedly forming an insulating layer 10 and a patterned wire 11 if needed. That is, the circuit board layer 12 of the laminated structure 13 shown in FIG. 3B is subjected to interlayer connecting and roughening treatment if needed. Then, an additional insulating layer 30 and an additional metal foil 15 are stacked in this order on the surface of the insulating layer 10 on which the patterned wire 11 is formed as shown in FIG. 3C, and bonded by heating and pressing with a press-molding machine. Thus, a further multilayered circuit board layer 12 can be formed on the removable copper foil attached substrate 5.

The copper foil 1 of the removable copper foil attached substrate 5 finally constitutes a part (specifically, an outer layer) of the circuit board 9. The copper foil 1 is made to adhere to the support layer 4 at an adhesion strength (particularly, 20 N/m or more) in the above-mentioned range of the peel strength in the removable copper foil attached substrate 5. Therefore, it is possible to prevent careless removal of the circuit board layer 12 from the removable copper foil attached substrate 5 during the buildup step. Further, it is possible to suppress spreading of a chemical or the like onto the interface between the copper foil 1 and the support layer 4 in the removable copper foil attached substrate 5 when a patterned wire is formed by patterning techniques involving chemical treatment such as etching or plating treatment.

In the removing step, as shown in FIG. 3D, the copper foil 1 is removed from the support layer 4 by applying a predetermined mechanical external force on the laminated structure 13. The removal interface between the copper foil 1 and the support layer 4 is an interface between the copper foil 1 and the release resin layer 2 in FIG. 3D. However, when a peel strength is within a range of 20 to 300 N/m, the removal interface may be an interface between the release resin layer 2 and the support layer 4 without strict limitation. The two circuit board layers 12 are separated from the support layer 4 by removing the copper foil 1 from the support layer 4 as described above, and thereby these can be obtained as the circuit boards 9. Since the peel strength is within a predetermined range (particularly, 300 N/m or less) at this time, stress applied during removing is less likely to cause an adverse effect such as breakage on the circuit board 9, and thereby the circuit board 9 having a good state can be obtained.

As described above, in the removable copper foil attached substrate 5, the release resin layer 2 allows removal of the copper foil 1 from the support layer 4. Thereby, the circuit board 9 can be obtained without requiring a cutting step by forming the circuit board layer 12 on the copper foil 1 by the buildup method by use of the removable copper foil attached substrate 5 as the temporary substrate. Thus, since the removable copper foil attached substrate 5 provides few production man-hours and causes no waste of raw materials, the coreless circuit board 9 can be easily produced at low production cost and low raw material cost as compared with a conventional example.

On the side edge face of the removable copper foil attached substrate 5, the interface between the copper foil 1 and the release resin layer 2 and the interface between the release resin layer 2 and the support layer 4 may be exposed. In this case, the peel strength for removal of the copper foil 1 from the support layer 4 is 20 N/m or more. Thereby, when the patterned wire 11 is formed, the chemical used for the chemical treatment such as etching or metal plating is less likely to spread onto the above interfaces, which can suppress the erosion of the copper foil 1.

The peel strength for removal of the copper foil 1 from the support layer 4 is 300 N/m or less, and thereby the copper foil 1 is removable from the support layer 4 by applying a comparatively small mechanical external force. The generation of strain in the circuit board 9 obtained by separating the circuit board layer 12 from the support layer 4 can also be suppressed.

### EXAMPLES

Hereinafter, the present invention will be specifically described with reference to Examples.

<Production of Prepreg>

Epoxy resins (YDB-500EK80 available from NSCC Epoxy Manufacturing Co., Ltd.: 64.67% by mass, and YDCN-220EK75 available from NSCC Epoxy Manufacturing Co., Ltd. Ltd.: 8.9% by mass), a curing agent (PHENOLITE TD-2090 60M available from DIC Corporation: 26.4% by mass), a curing accelerator (imidazole 2E4MZ available from Shikoku Chemicals Corporation: 0.03% by mass) were prepared as a resin ingredient. Based on 100 parts by mass of the resin ingredient, 180 parts by mass of an inorganic filler (spherical silica having an average particle diameter of 0.5 μm) was prepared. These were blended by use of methyl ethyl ketone as a solvent, to prepare a resin varnish.

A glass woven fabric base material (WEA7628 available from Nitto Boseki Co., Ltd., thickness of 0.18 mm) was impregnated with the resin varnish. The glass woven fabric base material was heated and dried at 150° C. in a drier, to produce prepreg 8 having a resin amount of 43% by mass and a melt viscosity 20000 poise. The prepreg 8 has a rectangular shape 340 by 510 mm in the plan view.

### Example 1

Sepanium Cu18B1C-M available from Sun Aluminium Industry, Ltd. (a release resin layer 2 was provided by coating a shiny surface of a copper foil 1 having a thickness of 18 μm and a size 340 by 510 mm with a release resin containing an epoxy resin serving as a film-forming resin and 30% by mass of a silicone additive agent based on the epoxy resin in an application amount of 1.5 g/m²) was used as a release resin layer attached copper foil 3. As shown in FIG. 2, four prepregs 8 were stacked. The prepregs 8 and the release resin layer attached copper foil 3 were stacked so that the release resin layer 2 was opposite the prepregs 8. They were heated and pressure molded with a press-molding machine to produce a removable copper foil attached substrate 5 as shown in FIG. 1. In this case, they were heated to 200° C. or higher (highest temperature: 210° C.) at a rising temperature rate of 2.5° C./minute, and pressed under a pressure of 2.9 MPa (30 kgf/cm²) for 90 minutes while this temperature was kept unchanged. The necessary quantity of the removable copper foil attached substrates 5 for each evaluation to be described later were produced.

### Examples 2 to 5

### Comparative Examples 1 and 2

Removable copper foil attached substrates 5 were produced in the same manner as in Example 1 except that the content of the silicone additive agent and the application amount of the release resin in the release resin in the release resin layer attached copper foil 3 of Example 1 were changed as shown in Table 1.

### Comparative Example 3

A removable copper foil attached substrate 5 was produced in the same manner as in Example 1 except that a career attached copper foil formed by providing an ultra-thin copper foil on a career copper foil (part number: MT18 available from Mitsui Mining and Smelting Co., Ltd.) was used in place of the release resin layer attached copper foil 3.

### <Measurement of Peel Strength (Removal Test)>

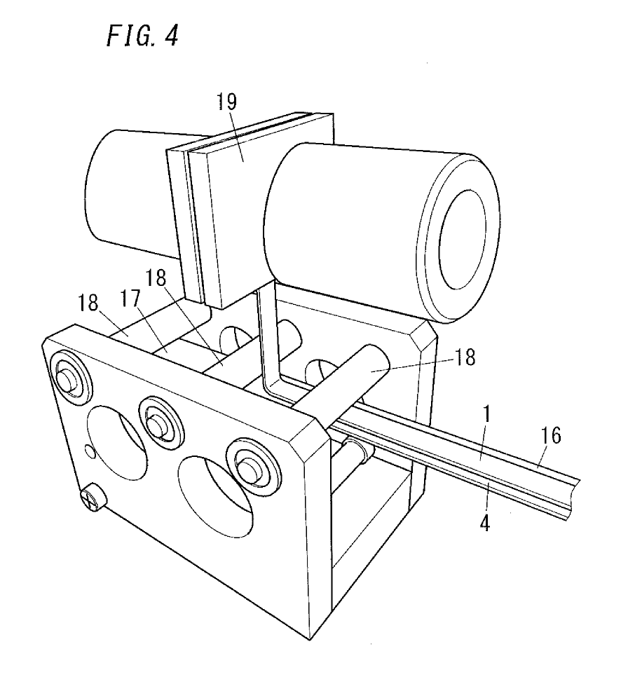

For each of the removable copper foil attached substrates 5 of Examples 1 to 5 and Comparative Examples 1 to 3, a peel strength for removal of a copper foil 1 from a support layer 4 was measured by use of a measuring apparatus shown in FIG. 4 based on a method specified in standard number C6481 in JIS. Specifically, a peel test piece 16 having a length of 10 cm and a width of 10 mm was cut out from the removable copper foil attached substrate 5. This peel test piece 16 was attached to a support plate 17, and fixed. An upper surface of the peel test piece 16 was pressed down with a plurality of roll bars 18. The copper foil 1 was partially picked up from an edge end part of the peel test piece 16 and clipped by a vice 19. This was perpendicularly pulled up, to remove the copper foil 1 from the peel test piece 16. A magnitude of a force required at this time was measured. The results are shown in Table 1.

TABLE 1

| | | Example | Example | Example | Example | Example | Comparative | Comparative | Comparative |
|---|---|---|---|---|---|---|---|---|---|
| | | 1 | 2 | 3 | 4 | 5 | Example 1 | Example 2 | Example 3 |
| Thickness of copper foil (μm) | | 18 | 18 | 18 | 18 | 18 | 18 | 18 | Use of career |
| Release | Film-forming | Epoxy | Epoxy | Epoxy | Epoxy | Epoxy | Epoxy | Epoxy | attached copper |
| resin layer | resin | | | | | | | | foil |
| | Additive | 30 | 10 | 0 | 40 | 0 | 50 | 0 | |
| | amount of | | | | | | | | |
| | silicone | | | | | | | | |
| | (% by mass) | | | | | | | | |
| | Amount applied | 1.5 | 0.6 | 1.5 | 2.5 | 0.3 | 3.0 | 0.2 | |
| | to copper foil | | | | | | | | |
| | (g/m²) | | | | | | | | |
| Support | Prepreg | 4ply | 4ply | 4ply | 4ply | 4ply | 4ply | 4ply | 4ply |
| layer | Thickness (mm) | 0.8 | 0.8 | 0.8 | 0.8 | 0.8 | 0.8 | 0.8 | 0.8 |
| Removal | Peel strength | 110 | 180 | 130 | 20 | 290 | 15 | 315 | 20 |
| test | (N/m) | | | | | | | | |

### <Manufacture of Evaluation Test Piece>

laminated structures 13 as shown in FIG. 3A were manufactured as evaluation test pieces 20 by use of the removable copper foil attached substrates 5 of Examples 1 to 5 and Comparative Examples 1 to 3.

Specifically, the above prepreg 8 was stacked on the surface of each of the copper foils 1 on both surfaces of the removable copper foil attached substrate 5, and a 12 μm-thick copper foil serving as a metal foil 15 was further stacked on the prepreg 8. These were heated and pressure molded for 90 minutes under conditions of a temperature of 200° C. and a pressure of 2.9 MPa for integral bonding by use of a press-molding machine in this state, and thereby the laminated structure 13 was manufactured as the evaluation test piece 20. The evaluation test piece 20 had a circuit board layer 12 formed on each of both surfaces of the removable copper foil attached substrate 5.

### <Chemical-Resistant Test (Evaluation of Etching Corrosive Property)>

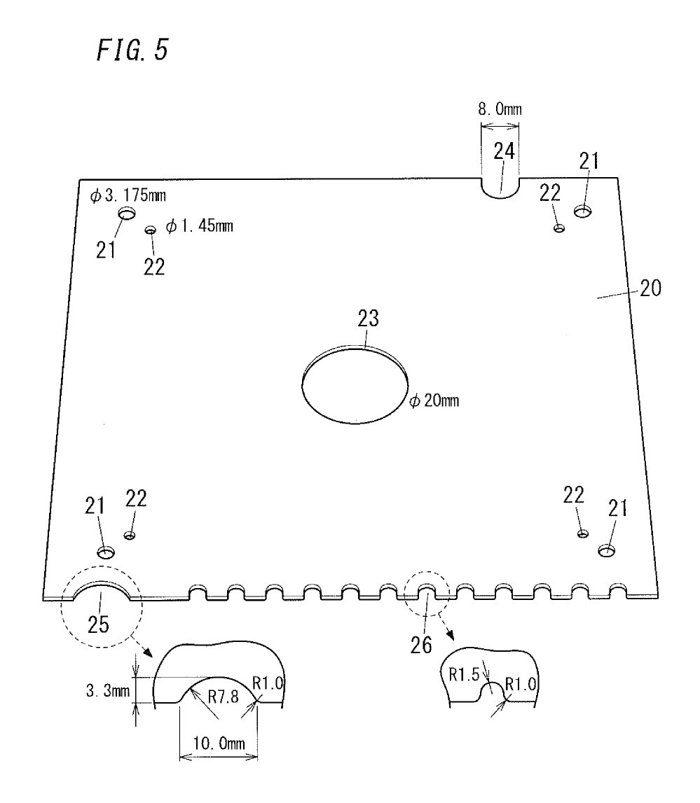

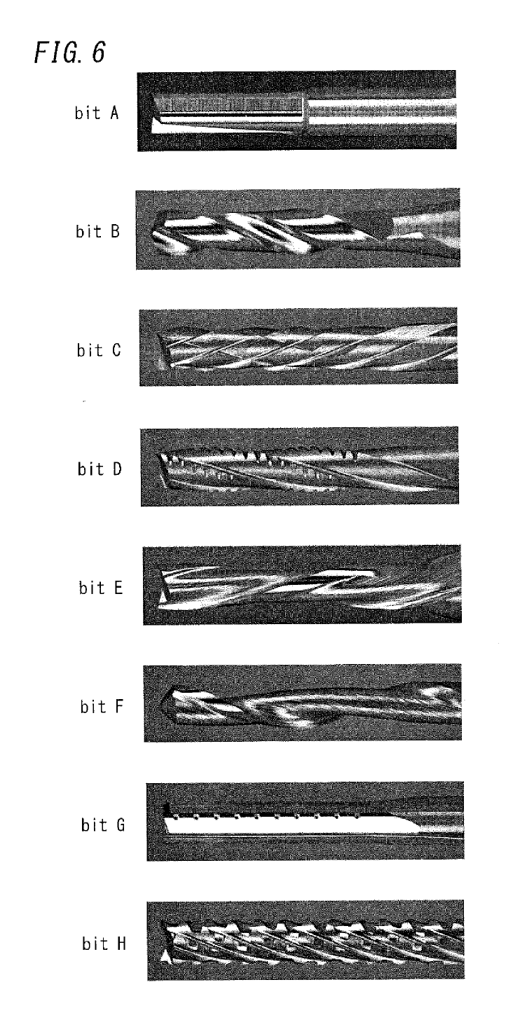

The evaluation test pieces 20 of Examples 1 to 5 and Comparative Examples 1 to 3 were subjected to router processing as shown in FIG. 5. Specifically, by router processing, a via hole 21 (φ3.175 mm) and a via hole 22 (φ1.45 mm) were formed in each of four corner parts of the evaluation test piece 20; a circular opening 23 (φ20 mm) was formed in a central part; a semicircle end face via 24 (φ8.0 mm) was formed in one end side part; and an almost semielliptical end face via 25 (long diameter: 10.0 mm, short diameter: 3.3 mm) and a plurality of almost semicircle end face vias 26 were formed in the other end side part. The router processing was carried out under different router processing conditions shown in Table 2 by use of blades having bits A to H having different shapes as shown in FIG. 6, for use as test pieces (1) to (9) for the router processing conditions.

TABLE 2

| | Router processing conditions | | | | | |
|---|---|---|---|---|---|---|
| | | Bit | Blade | Table | Feed | Revolution |
| Test | Bit | diameter | length | feed | (mm/ | speed |
| pieces | kind | (mm) | (mm) | (mm/min) | min) | (rpm) |
| (1) | A | 1 | 3 | 1250 | 300 | 30000 |
| (2) | B | 1 | 4 | 1250 | 300 | 30000 |
| (3) | C | 1 | 4.5 | 1250 | 50 | 30000 |
| (4) | D | 1 | 4.5 | 1250 | 300 | 30000 |
| (5) | E | 1 | 4.5 | 1250 | 300 | 30000 |
| (6) | F | 1 | 4.5 | 1250 | 300 | 30000 |
| (7) | G | 1 | 4.5 | 1250 | 300 | 30000 |
| (8) | G | 1 | 4.5 | 1250 | 50 | 30000 |
| (9) | H | 1 | 6.5 | 1250 | 50 | 30000 |

The above test pieces (1) to (9) were subjected to etching treatment to completely eliminate the metal foil 15 serving as an outermost layer. The etching treatment was performed under conditions of a temperature of 45° C., a pressure of 0.25 MPa, and an immersion time of 1 minute by use of an etching solution containing copper chloride, hydrochloric acid, and hydrogen peroxide as main ingredients (acid concentration: 3.3 mol/L). Then, the circumference of each via formed by the router processing and the end face part of the evaluation test piece 20 (test pieces (1) to (9)) were observed, and the copper foil 1 located as an inner layer was evaluated by confirming the presence or absence of erosion of the copper foil 1 by the etching solution. This evaluation was determined in visual observation. A copper foil having no erosion was determined to be “good”; a copper foil having erosion observed in a small proportion of router processing parts (less than twenty percent) was determined to be “average”; and a copper foil having erosion observed in many router processing parts (twenty percent or more) was determined to be “poor”. The evaluation results are shown in Table 3.

<Evaluation of Circuit Board after being Removed>

The circuit board layer 12 was separated as a circuit board 9 from the laminated structure 13 by removing the copper foil 1 from the support layer 4 in the evaluation test pieces 20 of Examples 1 to 5 and Comparative Examples 1 to 3. In this case, a force was applied to the evaluation test piece 20 to gradually separate the evaluation test piece 20 into two parts so that the copper foil 1 was manually removed from the support layer 4 with one corner part of the evaluation test piece 20 as a removal starting point in a state where the evaluation test piece 20 was placed on a flat work plane. The warpage of the circuit board 9, and the wrinkle and strain generated on the surface of the copper foil 1 or the metal foil 15 were confirmed by visual observation of the appearance. That is, in this evaluation, an evaluation test piece having no warpage and strain was determined to be “good”, and an evaluation test piece having warpage or strain was determined to be “poor”. The evaluation results are shown in Table 3.

TABLE 3

| | | Example | Example | Example | Example | Example | Comparative | Comparative | Comparative |
|---|---|---|---|---|---|---|---|---|---|
| | | 1 | 2 | 3 | 4 | 5 | Example 1 | Example 2 | Example 3 |
| Removal test | Peel | 110 | 180 | 130 | 20 | 290 | 15 | 315 | 15 |
| | strength | | | | | | | | |
| | (N/m) | | | | | | | | |
| Chemical- | Test piece | Good | Good | Good | Good | Good | Poor | Good | Average |
| resistant test | (1) | | | | | | | | |
| (evaluation | Test piece | Average | Good | Good | Average | Good | Poor | Good | Poor |
| of etching | (2) | | | | | | | | |
| corrosive | Test piece | Average | Good | Good | Average | Good | Poor | Good | Poor |
| property) | (3) | | | | | | | | |
| | Test piece | Average | Good | Good | Average | Good | Poor | Good | Poor |
| | (4) | | | | | | | | |
| | Test piece | Average | Good | Good | Average | Good | Poor | Good | Poor |
| | (5) | | | | | | | | |
| | Test piece | Average | Good | Good | Average | Good | Poor | Good | Poor |
| | (6) | | | | | | | | |
| | Test piece | Average | Good | Good | Average | Good | Poor | Good | Poor |
| | (7) | | | | | | | | |
| | Test piece | Average | Good | Good | Average | Good | Poor | Good | Poor |
| | (8) | | | | | | | | |
| | Test piece | Average | Good | Good | Average | Good | Poor | Good | Poor |
| | (9) | | | | | | | | |

| | | | | | | | | |
|---|---|---|---|---|---|---|---|---|
| Evaluation of circuit board | Good | Good | Good | Good | Good | Good | Poor | Good |
| after being removed from | | | | | | | | |
| support layer | | | | | | | | |

As apparent from Table 3, in Examples 1 to 5 including the removable copper foil attached substrate 5 in which the peel strength for removal of the copper foil 1 from the support layer 4 was 20 to 300 N/m, good results were obtained in the chemical-resistant test after the router processing. In addition, the warpage and strain of the circuit board 9 were not observed also in the evaluation after the copper foil 1 was removed from the support layer 4. In Examples 1 and 4, etching erosion was observed in a very small part depending on the router processing conditions. However, it was found that the erosion can be suppressed by appropriately selecting the router processing conditions. Particularly, in Examples 2, 3, and 5 including the removable copper foil attached substrate 5 in which the peel strength for removal of the copper foil 1 from the support layer 4 was 120 to 300 N/m, etching erosion was not observed in the chemical-resistant test in the evaluation test pieces 20 under all the router processing conditions.

On the other hand, in Comparative Example 1 having a peel strength of less than 20 N/m and Comparative Example 3 including the career attached copper foil, etching erosion was generated in the chemical-resistant test in all the evaluation test pieces 20. In Comparative Example 2 having a peel strength exceeding 300 N/m, the result of the chemical-resistant test was good. However, the warpage and strain of the circuit board 9 were generated in the evaluation after being removed from the support layer 4.

### DESCRIPTION OF REFERENCE NUMERALS

1 Copper foil
2 Release resin layer
3 Release resin layer attached copper foil
4 Support layer
5 Removable copper foil attached substrate
6 Base material
7 Resin
8 Prepreg
9 Circuit board
10 Insulating layer
11 Patterned wire
12 Circuit board layer
13 Laminated structure

1. A removable copper foil attached substrate comprising:
a release resin layer attached copper foil including a copper foil and a release resin layer attached on a surface of the copper foil; and
a support layer,
the release resin layer attached copper foil being integrally bonded to the support layer with the release resin layer in-between,
the release resin layer allowing removal of the copper foil from the support layer, and
a peel strength for removal of the copper foil from the support layer being 20 to 300 N/m.

2. The removable copper foil attached substrate according to claim 1, wherein
the one surface of the copper foil on which the release resin layer is provided is a shiny surface.

3. The removable copper foil attached substrate according to claim 1, wherein
a further surface of the copper foil is a matte surface.

4. The removable copper foil attached substrate according to claim 1, wherein
the release resin layer attached copper foil is integrally attached to each of both surfaces of the support layer.

5. The removable copper foil attached substrate according to claim 1, wherein
the support layer made from prepreg prepared by impregnating base material with resin.

6. A method for producing at least one circuit board by use of the removable copper foil attached substrate according to claim 1 as a temporary substrate,
the method comprising:
a buildup step of preparing a laminated structure by forming at least one circuit board layer on the removable copper foil attached substrate by performing a step of forming an insulating layer on a copper foil of the removable copper foil attached substrate and a patterned wire on the insulating layer by patterning techniques involving chemical treatment and an optional step of performing at least one time sub-step of an additional insulating layer and an additional patterned wire; and
a removing step of removing the copper foil from the support layer in the laminated structure to separate the at least one circuit board layer serving as the at least one circuit board.
